(19) United States
(12) Patent Application Publication
(10) Pub. No.: US 2024/0094553 A1
(43) Pub. Date: Mar. 21, 2024

(54) Emitter Array with Integrated Beam-Splitting Prisms

(71) Applicant: Apple Inc., Cupertino, CA (US)

(72) Inventors: Roei Remez, Tel Aviv (IL); Omer Korech, Pardes Hanna Karkur (IL); Niv Gilboa, Tel Aviv (IL)

(21) Appl. No.: 17/945,886

(22) Filed: Sep. 15, 2022

(51) Int. Cl. G02B 27/12; G02B 27/10; H01S 5/183

(52) U.S. Cl. CPC G02B 27/126; G02B 27/1086; H01S 5/18386

(57) ABSTRACT

Various embodiments disclosed herein light source arrays with integrated beam-splitting prisms. The beam-splitting prisms are formed in a surface of a substrate, such as a semiconductor substrate, and split input beams generated by an array of emitters. The beam-splitting prisms each include a plurality of prism surfaces that generate a different output beam.

### FIELD

This disclosure relates generally to emitter arrays, and particularly emitter arrays that include an array of beam-splitting prisms.

### BACKGROUND

Light emitting arrays are often used to generate either flood illumination, in which the light emitting module attempts to illuminate an entire target region with uniform illumination, or structured illumination, in which the illumination varies spatially to contain spatial features (e.g., by projecting a pattern of spots onto the target region). Particularly when the emitters of the light emitting module are vertical-cavity surface-emitting lasers (VCSELs), the emitters may have high native beam divergence (e.g., due to a relatively short resonator length). To reduce this divergence, the light emitting module may include integrated microlenses positioned over respective emitters. In these instances, an emitter of the light emitting module may be formed on a first surface of a substrate and a corresponding microlens may be formed on an opposite surface of the substrate in alignment with the emitter. A beam of light generated by the emitter will pass through the substrate and will be collimated by the microlens.

When a light emitting module is used to provide flood illumination, it is generally preferable to provide uniform illumination across the target region in a space- and cost-efficient manner. Depending on the design of the light emitting module, failure of an individual emitter may result in a portion of the target region that does not receive illumination. When the light emitting module is incorporated into a system that utilizes flood illumination for one or more purposes (such as capturing an image of the target region while under illumination), failure of an emitter may interfere with the intended operation of the system.

### SUMMARY

The present disclosure relates to light source arrays with beam-splitting prisms. In some embodiments, a light source array includes a substrate having first and second surfaces and an array of emitters, wherein a light-emitting surface of each of the array emitters is positioned to emit an input beam into the substrate through the second surface of the substrate. The light source array includes an array of beam-splitting prisms, which are formed on the first surface of the substrate. Each beam-splitting prism of the array of beam-splitting prisms is positioned to split the input beam emitted by a corresponding emitter of the array of emitters to generate a plurality of output beams, and includes a plurality of prism surfaces positioned to generate the plurality of output beams by redirecting respective portions of the input beam.

In some instances, the array of beam-splitting prisms includes a first beam-splitting prism, wherein the plurality of prism surfaces of the first beam-splitting prism are arranged as a pyramid. In some of these instances, an apex of the pyramid faces toward the second surface of the substrate. In other instances, the array of beam-splitting prisms comprises a first beam-splitting prism, wherein the plurality of prism surfaces of the first beam-splitting prism comprises a first prism surface and a second prism surface. In some of these instances, the first prism surface and the second prism surface are angled toward a common side of the light emitting module. In other instances, the first prism surface and the second prism surface are angled toward different sides of the light emitting module.

In some instances, the array of emitters is formed on the second surface of the substrate. The array of emitters may include vertical-cavity surface-emitting lasers (VCSELs). In some variations, a diffractive optical element is positioned to create multiple replicas of the output beams generated by the array of beam-splitting prisms. Additionally or alternatively, the array of beam-splitting prisms may include a first beam-splitting prism and a second beam-splitting prism, wherein an output beam generated by the first beam-splitting prism substantially overlaps an output beam generated by the second beam-splitting prism in a scene illuminated by light emitting module.

Other embodiments are directed toward an optical device having a substrate with a first surface and a second surface, wherein the first surface is etched to define an array of beam-splitting prisms configured to split input beams of light that have been transmitted through the substrate, and each beam-splitting prism of the array of beam-splitting prisms comprises a plurality of prism surfaces arranged as a pyramid. In some instances, the substrate comprises a III-V semiconductor substrate. Additionally or alternatively, the array of beam-splitting prisms may include a first prism, wherein the plurality of prism surfaces of the first prism are arranged as a pyramid with an apex facing toward the second surface of the substrate. In other instances, the array of beam-splitting prisms may include a first prism, wherein the plurality of prism surfaces of the first prism are arranged as a pyramid with an apex facing away from the second surface of the substrate

Still other embodiments are direct to a light emitting module that includes a substrate having first and second surfaces, an array of emitters positioned to emit respective input beams into the substrate through the second surface of the substrate, and an array of beam-splitting prisms configured to split each of the input beams to generate a corresponding plurality of output beams. The first array of emitters is controllable to emit flood illumination to a target illumination region such that each location within the target illumination region is illuminated by output beams generated by at least two beam-splitting prisms of the array of beam-splitting prisms.

In some of these instances, the array of beam-splitting prisms comprises a first beam-splitting prism and a second beam-splitting prism, and a first output beam generated by the first beam-splitting prism substantially overlaps with a first output beam generated by the second beam-splitting prism. In some of these variations, a second output beam generated by the first beam-splitting prism substantially overlaps with a second output beam generated by the second beam-splitting prism. In other variations, the array of beam-splitting prisms comprises a first beam-splitting prism and a second beam-splitting prism, and a first output beam generated by the first beam-splitting prism is projected between first and second output beams generated by the second beam-splitting prism without substantially overlapping the first and second output beams generated by the second beam-splitting prism.

In other variation, the array of beam-splitting prisms comprises a first beam-splitting prism, a second beam-splitting prism, and a third beam-splitting prism. The first output beam generated by the first beam-splitting prism substantially overlaps a first output beam generated by the second beam-splitting prism, and a second output beam generated by the first beam-splitting prism substantially overlaps a first output beam generated by the third beam-splitting prism. In some of these instances, a third output beam generated by the first beam-splitting prism substantially overlaps a second output beam generated by the second beam-splitting prism.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows a sectional side view of a light emitting module having integrated microlenses. FIGS. 1B and 1C show a representation of an illumination region as illuminated by the light emitting module of FIG. 1A.

FIGS. 2A and 2B show perspective and sectional side views, respectively, of a portion of a light emitting module as described herein that includes a variation of an integrated beam-splitting prism.

FIGS. 2C and 2D show perspective and sectional side views, respectively, of a portion of a light emitting module as described herein that includes another variation of an integrated beam-splitting prism.

FIGS. 2E and 2F show perspective and sectional side views, respectively, of a portion of a light emitting module as described herein that includes still another variation of an integrated beam-splitting prism.

FIGS. 2G and 2H show perspective and sectional side views, respectively, of a portion of a light emitting module as described herein that includes yet another variation of an integrated beam-splitting prism.

FIG. 3A shows a sectional side view of an illustrative example of a light emitting module having integrated beam-splitting prisms. FIG. 3B shows example illumination provided by the portion of the light emitting module depicted in FIG. 3A.

FIG. 4A shows a schematic representation of emitter-prism pairs of a light emitting module as described herein. FIG. 4B shows a schematic representation of an illumination region as illuminated by the emitter-prism pairs of FIG. 4A.

It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

Directional terminology, such as “top”, “bottom”, “upper”, “lower”, “front”, “back”, “over”, “under”, “above”, “below”, “left”, “right”, “vertical”, “horizontal”, etc. is used with reference to the orientation of some of the components in some of the figures described below, and is not intended to be limiting. Because components in various embodiments can be positioned in a number of different orientations, directional terminology is used for purposes of illustration only and is in no way limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

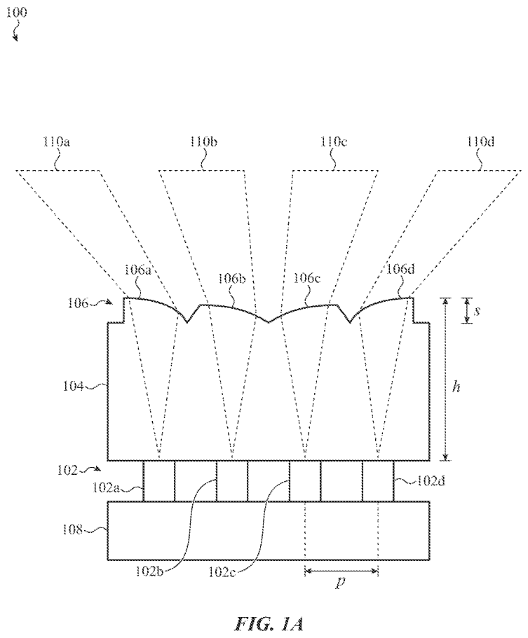

The following disclosure relates to light emitting modules including integrated beam-splitting prisms. Each beam-splitting prism includes a plurality of prism surfaces that redirect different portions of beam of light generated by an emitter in order to split that beam of light into multiple output beams. Splitting a beam of light using a beam-splitting prism may allow for greater beam deflection as compared to non-splitting microlenses for a given sag depth (as discussed below), and when used collectively, may provide redundancy by allowing light redirected from multiple beam-splitting prisms to illuminate a given portion of a target illumination region. These and other embodiments are discussed below with reference to FIGS. 1A-4B. However, those skilled in the art will readily appreciate that the detailed description given herein with respect to these Figures is for explanatory purposes only and should not be construed as limiting.

FIG. 1A shows a sectional side view of a light emitting module 100. As shown there, the light emitting module 100 includes an array of emitters 102 and a substrate 104 with an array of microlenses 106 formed on a first surface of the substrate 104. Four emitters 102a-102d and four microlenses 106a-106d are shown in FIG. 1A, and an emission surface of each emitter is aligned relative to a corresponding microlens so that it receives light from the emitter. For example, a first emitter 102a may emit a first beam of light 110a toward a first microlens 106a, which collimates the first beam of light 110a as it exits the substrate 104. Similarly, the second, third, and fourth emitters 102b, 102c, and 102d may emit corresponding second, third, and fourth beams of light 110b, 110c, and 110d, that are collimated by second, third, and fourth microlenses 106b, 106c, and 106d.

The substrate 104 is formed from a material that allows light emitted by the array of emitters 102 to travel therethrough, and in some instances may be a semiconductor substrate such as a III-V semiconductor substrate (e.g., made from GaAs or the like). In some instances the array of emitters 102 may be VCSELs that are formed on a second surface of the substrate 104 at locations that align light-emitting surface of the VCSELs with respective microlenses of the array of microlenses 106. Additionally, a control substrate 108 (e.g., a silicon wafer or like) may be bonded to the array of emitters 102 to provide the electrical connections needed in order to actuate and drive the array of emitters 102. For example, the control substrate 108 may include conductive lines that are electrically connected to the emitters 102 to carry one or more drive signals thereto. The application of a drive signal to a given emitter will actuate the emitter to generate light. The array of emitters 102 may be individual actuated (e.g., by applying individual drive signals to each individually-actuated emitter) or may be actuated as a group (e.g., by applying a common drive signal to a group of emitters).

The light emitting module 100 may be configured to provide structured and/or flood illumination to a target region of a scene (hereinafter referred to as an “illumination region” or “target illumination region”). In these instances where a light emitting module 100 is controllable to provide flood illumination, the beams of light 106a-106d may be simultaneously projected onto the illumination region in a manner where every point in the illumination region is illuminated by at least one of the beams of light 106a-106d. For example, FIG. 1B shows a representation of a scene 112 that is positioned to receive light from the light emitting module 100 of FIG. 1A. As shown there, an illumination region 114 is illuminated using flood illumination from the light emitting module 100.

Specifically, a plurality of light beams (including the first, second, third, and fourth beams of light 110a-110d from FIG. 1A) are projected from the light emitting module 100 onto the illumination region 114 as shown in FIG. 1B. For the purpose of illustration, a 3×4 array of emitters 102 may project twelve beams onto the illumination region 114 to fully illuminate the illumination region 114. The portion of the illumination region 114 that is illuminated by a given emitter depends on the angle at which the emitter's beam of light exits a corresponding microlens, as well as the divergence of the beam of light as it exits the corresponding microlens. Accordingly, the surfaces of certain microlenses may be tilted to redirect beams toward different portions of the illumination region 114. For example, the emitters near a center of the light emitting module 100 may be associated with microlenses that are tilted less than microlenses positioned at a periphery of the light emitting module 100, which may allow the light emitting module 100 to cover a larger illumination region 114.

As shown in FIG. 1B, there may be some overlap between adjacent light beams projected onto the illumination region 114 (e.g., the second light beam 110b partially overlaps the first and third light beams 110a and 110c in the illumination region 114), but most of the illumination region 114 is illuminated by a single beam of light. In general, to improve the efficiency of the illumination provided by the light emitting module 100, it may be desirable to reduce the overlap between adjacent beams of light. This may be done by reducing the divergence of the individual beam of light emitted by the light emitting module 100, which thereby reduces the amount of overlap between adjacent beams.

Generally, increasing the height “h” of the substrate 104 may reduce the divergence of a beams of light as they exit the substrate 104. Specifically, the increased height of the substrate allows the beams of light generated by each emitter to diverge to a larger diameter before being collimated by a microlens. Increasing this height, however, may also require a corresponding increase in the size of the individual microlenses 106, and with it, the pitch “p” between the emitters 102 that are used to provide the flood illumination. This may result in an increase in the overall size and cost of the light emitting module 100. Additionally, increasing the height may also increase the amount of tilt required to direct a particular beam of light to a given portion of the illumination region 114, which increases the amount of lens sag “s” required of the array of microlenses 106 to achieve this tilt. Because the manufacturing processes that are used to form the array of microlenses 106 (e.g., etching a surface of the substrate 104 to form the microlenses 106) may only be able to create microlenses with a certain amount of lens sag, this may effectively limit the height of the substrate 104 or limit the angular extent to which the beams of light may be redirected.

Additionally, failure of a particular emitter of the light emitting module 100 may impede the ability of the light emitting module 100 to fully illuminate the target illumination region. For example, FIG. 1C shows the scene 112 and illumination region 114 in an instance where the first emitter 102a of the light emitting module 102 is not operating to emit the first beam of light 110a. While the remaining emitters may still generate their corresponding beams of light, a portion of the illumination region 114 will not receive any illumination. This may interfere with the operation of another component of a system that relies on illumination of the entire illumination region, such as a camera or depth sensor that utilizes this illumination to capture information about the illumination region 114. Doubling the number of emitters 102 (e.g., having two emitters aligned with a single microlens) may provide redundancy in the case of a failure of one emitter, but also increases the cost and complexity of the light emitting module 102. Similarly, increasing the divergence of the plurality of the beams of light to increase the overlap between adjacent beams may also provide some redundancy, but may decrease the efficiency of the illumination (e.g., may increase the amount of energy that is spent illuminating regions of the scene 112 outside of the illumination region 114).

Accordingly, the light emitting modules described herein may include one or more beam splitting prisms that are positioned to split a beam of light generated by a corresponding emitter. The light emitting module may be configured in any suitable manner as described above with respect to the light emitting module of FIG. 1A, except that some or all of the array of microlenses is replaced with a beam-splitting prism. The light emitting module may include one or more types of beam-splitting prisms, which may provide flexibility in using these beam-splitting prisms to provide illumination.

Each beam-splitting prism includes a plurality of prism surfaces, and is aligned relative to an emission surface of a corresponding emitter so that each prism surface receives a corresponding portion of a beam of light (also referred to herein as the “input beam”) generated by the emitter. Each prism surface will redirect the portion of the input beam that it receives, thereby creating a separate beam of light (also referred to herein as an “output beam”). Accordingly, the beam-splitting prism will split an input beam generated by an emitter into a plurality of separate output beams. The number of output beams generated by a beam-splitting prism depends on the number of prism surfaces that receive a corresponding portion of an input beam. Accordingly, a beam-splitting prism may include two, three, four, or more prism surfaces that generate two, three, four, or more output beams. Overall, a light source array may emit a larger number of output beams than the number of emitters included in the light emitting module.

Each prism surface will direct its corresponding output beam along a direction that depends on an orientation of the prism surface, including the angle at which the prism surface is orientated and the direction in which the prism surface faces. Additionally, some or all of the prism surfaces may be curved to collimate or otherwise adjust the divergence the output beams. As compared to a single-surface microlens as such as discussed about with respect to FIGS. 1A and 1B, having multiple prism surfaces allows each surface to have a target tilt angle with less lens sag. Accordingly, the beam splitting prism can be designed to either redirect the output beams at a steeper angle compared to the microlenses 106 discussed above for the same amount of lens sag, or may achieve an equivalent amount of redirection with less lens sag.

Additionally, in instances where an emitter such as a VCSEL produces a multi-mode beam of light (e.g., with a M² factor greater than 1), the divergence of each of the output beams may not significantly increase as compared to the divergence of the input beam. A given prism surface may receive a subset of the lobes of the modes of an input beam when generating an output beam, which may thereby reduce the M² factor of the output beam as compared to the input beam. This reduction in M² factor may at least partially offset the increased divergence that would otherwise be created by reducing the beam diameter when an output beam is generated. Indeed, depending on the number of prism surfaces/output beams and the mode profile of the emitter, it may be possible for the divergence of each output beam to be approximately the same as the divergence of an output beam emitted by a microlens 106 as discussed above with respect to FIG. 1A.

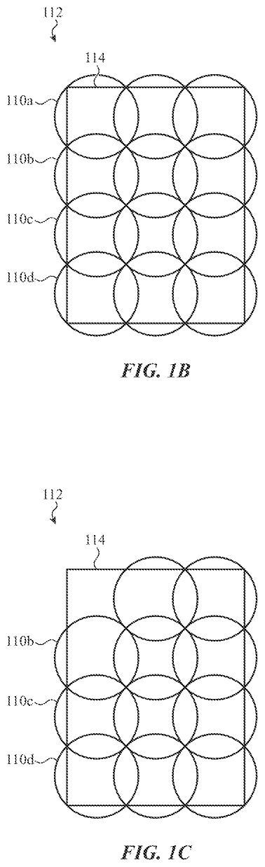

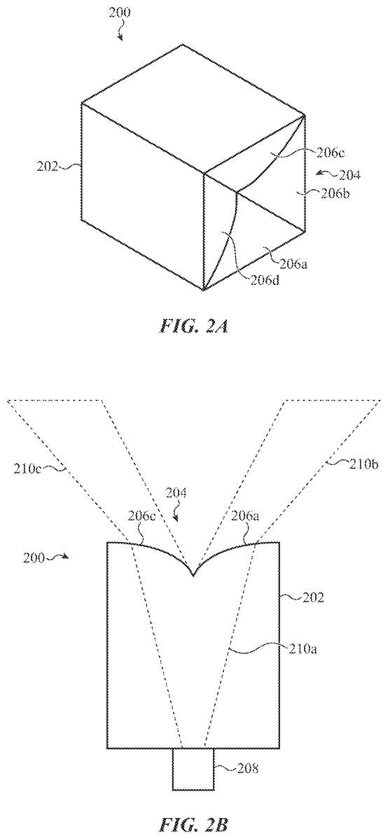

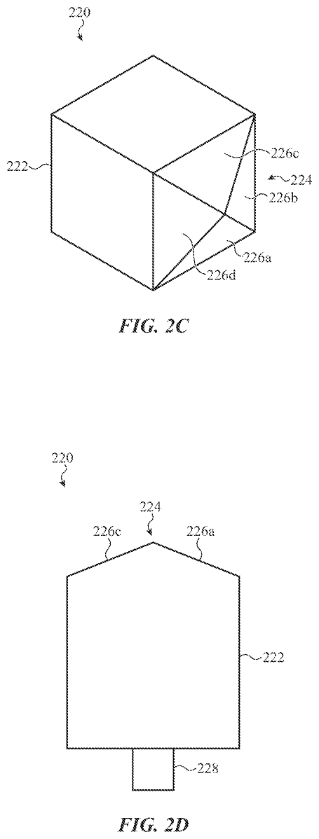

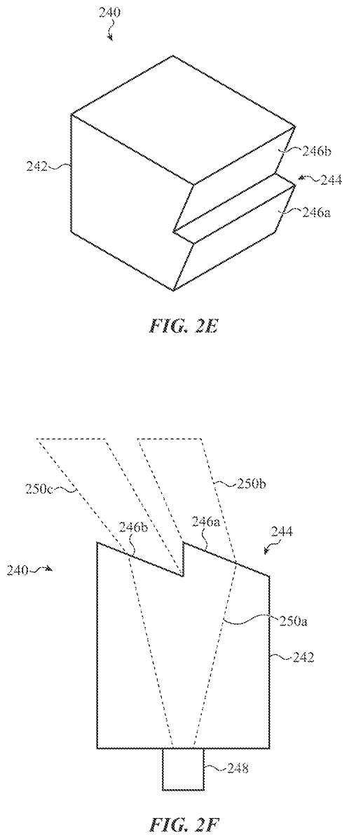

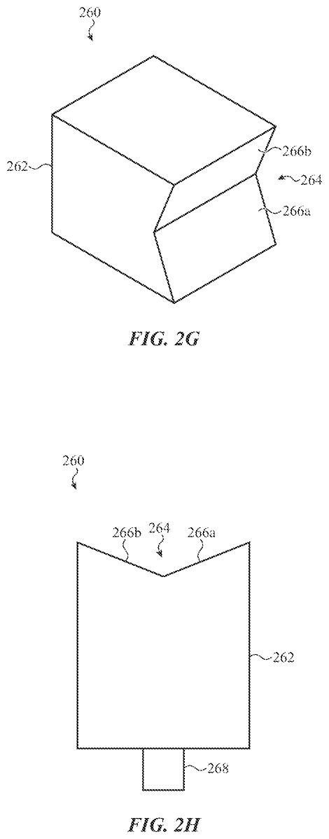

FIGS. 2A-2H show a number of variations of beams-splitting prisms that may be used with the light emitting modules described herein. In some instances the beam-splitting prism may include a plurality of prism surfaces arranged as a pyramid (i.e., the prism surfaces act as lateral surfaces of a pyramid having a base and an apex). For example, FIGS. 2A and 2B show perspective and sectional side views of a portion of a light emitting module 200 having a substrate 202 with a beam-splitting prism 204 formed in a first surface thereof. In this variation, the beam-splitting prism 204 includes four prism surfaces (206a-206d) arranged as a pyramid having a square base. When aligned with a light-emitting surface of an emitter 208 as shown in FIG. 2B (which may be formed on or otherwise positioned against a second surface of the substrate 202), the beam-splitting prism 204 may split an input beam 210a generated by the emitter 208 into four different output beams. Specifically, each of the prism surfaces 206a-206d will redirect a corresponding portion of the input beam 210a to form a separate output beam. For example, FIG. 2B shows a first prism surface 206a forming a first output beam 210b and a second prism surface 206c forming a second output beam 210c.

Each of the prism surfaces 206a-206d are shown in FIGS. 2A-2B as being curved, which may act to collimate or otherwise alter the divergence of the output beams (e.g., output beams 210b and 210c), though it should be appreciated that some or all of the prism surfaces 206a-206d may alternatively be flat. Similarly, while shown in FIGS. 2A and 2B as having four prism surfaces 206a-206d, the beam-splitting may include a different number of prism surfaces arranged as a pyramid (e.g., three prism surfaces arranged as a pyramid with a triangular base, five prism surfaces arranged as a pyramid with a pentagonal base, or the like).

The pyramid formed by the prism surfaces 206a-206d has an apex facing the emitter 208 (i.e., the emitter 208 is closer to apex of the pyramid than it is to the base), thereby forming an inverted pyramid. FIGS. 2C and 2D show perspective and sectional side views of a portion of a light emitting module 220 having a substrate 222 with a beam-splitting prism 224 formed in a first surface thereof. In this variation, the beam-splitting prism 224 includes four prism surfaces (226a-226d) arranged as a pyramid in which the apex surface s away from an emitter 228 (i.e., the emitter 228 is closer to the base of the pyramid than it is to the apex). As with the beam-splitting prism 204 of FIGS. 2A and 2B, the beam-splitting prism 224 may be positioned to split an input beam (not shown) from the emitter 228 into four output beams (not shown). Similarly, the beam-splitting prism 224 may be configured with a different number of prism surfaces (each of which may be curved or flat) such as discussed above.

In some instances, a beam-splitting prism may include two prism surfaces that split an input beam into two output beams. FIGS. 2E and 2F show perspective and sectional side views of a portion of a light emitting module 240 having a substrate 242 with a beam-splitting prism 244 formed in a first surface thereof. The beam-splitting prism 244 includes a first prism surface 246a and a second prism surface 246b, each of which is configured to redirect a corresponding portion of an input beam to form an output beam. When aligned with a light-emitting surface of an emitter 248 as shown in FIG. 2F (which may be formed on or otherwise positioned against a second surface of the substrate 242), the beam-splitting prism 244 may split an input beam 250a generated by the emitter 248 into first and second output beams 250b and 250c.

In the variation shown in FIGS. 2E and 2F, the beam-splitting prism 244 defines an area that is equally divided between the first prism surface 246a and the second prism surface 246b, though in other instances an unequal division may be applied if so desired. Additionally, as shown there the first and second prisms surfaces 246a and 246b are angled toward a common side of the light emitting module 240, and thus the output beams 250b and 250c are angled toward the common side of the light emitting module 240. In other variations, the prism surfaces 246a and 246b may be angled toward different sides of the light emitting module 240.

For example, FIGS. 2G and 2H show perspective and sectional side views of a portion of a light emitting module 260 having a substrate 262 with a beam-splitting prism 264 formed in a first surface thereof. The beam-splitting prism 264 includes a first prism surface 266a and a second prism surface 266b, each of which is configured to redirect a corresponding portion of an input beam to form an output beam. When aligned with a light-emitting surface of an emitter 268 as shown in FIG. 2H (which may be formed on or otherwise positioned against a second surface of the substrate 262), the beam-splitting prism 264 may split an input beam (not shown) generated by the emitter 268 into first and second output beams. In this variation, the first and second prism surfaces 266a and 266b are angled toward opposite sides of the light emitting module 260, and thus the output beams will be angled toward opposite sides of the light emitting module 260.

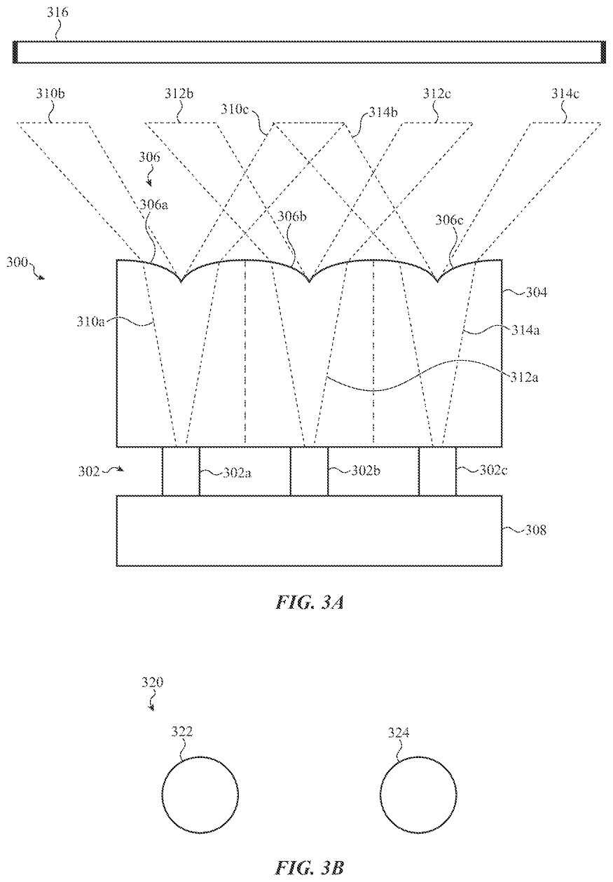

The beam-splitting prisms described in FIGS. 2A-2H are just a few examples of beam-splitting prisms that may be used to split an input beam into multiple output beams, and the light emitting modules described here may include any combination and number of beam-splitting prisms as desired. For example, FIG. 3A shows a sectional side view of a variation of a light emitting module 300. As shown there, the light emitting module 300 includes an array of emitters 302 and a substrate 304 with an array of beam-splitting prisms 306 formed on a first side of the substrate 304. Three emitters 302a-302c and three beam-splitting prisms 306a-306c are shown in FIG. 3A, and an emission surface of each emitter is aligned relative to a corresponding beam-splitting prism so that the beam-splitting prism receives and splits an input beam emitted by the emitter.

The beam-splitting prisms 306a-306c are shown in FIG. 3A as each being configured to split an input beam into two output beams, and are each configured as described above with respect to the beam-splitting prisms 264 of FIGS. 2G and 2H (except shown in FIG. 3A with curved prism surfaces). A first emitter 302a may emit an input beam 310a toward the first beam-splitting prism 306a, which generates a first output beam 310b and a second output beam 310c as light exits the substrate 304. Similarly, the second beam-splitting prism 306b splits an input beam 312a from the second emitter 302b into two output beams 312b and 312c, and the third beam-splitting prism 306c splits an input beam 314a from the third emitter 302c into two output beams 314b and 314c. While the beam-splitting prisms 306a-306c are shown as each having the same configuration, it should be appreciated that the different beam-splitting prisms within the light emitting array 300 may be configured differently (e.g., have different numbers of prism surfaces, have prism surfaces oriented at different angles and/or directions) in order to illuminate different portions of a scene, as will be described in more detail below.

The array of emitters 302 may include any suitable component capable of generating an input beam. In some variations the array of emitters 302 is an array of VCSELs. In some of these variations, the VCSELs are formed on a second surface of the substrate 304 as discussed previously. A control substrate 308 (e.g., a silicon wafer or like) may be bonded to the array of emitters 302 to provide the electrical connections needed in order to actuate and drive the array of emitters 302, such as described above. In other instances, an optical fiber, waveguide (e.g., of a photonic integrated circuit), or other optical connector may couple light from an emitter into the substrate 304, in which instances the light-emitting surface of the emitter would be considered the portion of the optical connector that couples the input beam into the substrate 304.

The light emitting module 300 may be configured to provide structured light and/or flood illumination. For example, in instances where emitters or groups of emitters of the array of emitters 302 are independently controllable, different sets of emitters may be activated to selectively provide structured light or flood illumination. For example, a first set of emitters may be activated to provide structured illumination to a target illumination region (e.g., by illuminating only a portion of the target illumination region or by illuminating certain portions of the target illumination region with a different intensity than other portions of the illumination). A second set of emitters (which may include some or all of the first set of emitters) may be activated to provide flood illumination to the target illumination region. The first and second arrays of emitters may be separately controllable to selectively provide flood or structured illumination. In other instances, the light emitting module 300 may be configured to only provide flood illumination or to only provide structured illumination.

In some variations, the light emitting module 300 may include a diffractive optical element 316 positioned to receive the output beams emitted from the first surface of the substrate 304. The diffractive optical element 316 may create multiple replicas of the illumination generated by the array of emitters, and may thereby increase the size of a target illumination region illuminated by the light source array 300.

In some instances, a beam-splitting prism may direct an output beam generated therefrom so that it overlaps an output beam generated by a different beam-splitting prism when projected onto a scene. As mentioned above, the spatial portion of an illumination region illuminated by a given output beam is based at least in part on the angle and the direction of the output beam as it leaves the substrate 304. In this way, a given region of the target illumination region will receive illumination from multiple beam-splitting prisms (and their respective emitters) if those beam-splitting surfaces have corresponding prisms surfaces with similar orientations.

For example, FIG. 3B shows a portion of a scene 320 illuminated by the first, second, and third emitters 302a-302c of the light emitting module 300 of FIG. 3A. Because the first, second, and third beam-splitting prisms are shown in FIG. 3A as being identical, the output beams of these emitters will illuminate the same regions of the scene. Accordingly, the scene 320 includes a first region 322 that is illuminated by the first output beam from each of the second, and third emitters 302a-302c (i.e., the first output beams 310b, 312b, and 314b). The scene further includes a second region 324 that is illuminated by the second output beam from each of the second, and third emitters 302a-302c (i.e., the second output beams 310c, 312c, and 314d). In these instances, the first and second regions 322, 324 will receive illumination from the light emitting array even if one or two of these emitters fails.

Accordingly, the light emitting modules (such as light emitting module 300) may be configured such that output beams created by prism surfaces of two or more beam-splitting prisms substantially overlap when projected onto a scene. In these instances, the corresponding prism surfaces of these beam-splitting prisms are designed to have the same angle and orientation. Depending on the manufacturing tolerances, there may be slight variations between the prisms surfaces of these beam-splitting prisms, and thus two output beams are considered to substantially overlap with each other if at least 80% of each output beam overlaps with the other when projected onto a scene. When two or output beams substantially overlap at a particular region of the scene, that region of the scene may be illuminated by any or all of the light emitters that generate these output beams. This may provide a level of redundancy in case one of these emitters fails, as the other emitter may still be able to provide some illumination to this region.

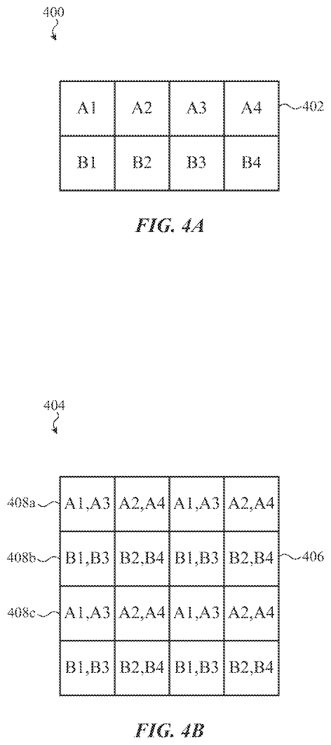

When a light emitting module that includes beam-splitting prisms is used to provide flood illumination to a target illumination region, the light emitting module may be configured such that every location in the target illumination region is illuminated by at least two emitters. For example, FIGS. 4A and 4B depict a manner in which a light emitting module 400 having an array of emitters and an array of beam-splitting prisms may be used to provide flood illumination to a scene, specifically to a target illumination region 404 within the scene.

For the purpose of illustration, the light emitting module 400 is depicted by an array of emitter-prism pairs 402. Each emitter-prism pair includes an emitter and a beam-splitting prism, where the beam-splitting prism is positioned to split an input beam generated by the emitter into a plurality of output beams. In FIG. 4A, the array of emitter-prism pairs 402 is configured as a 2×4 array that includes two rows, each having four emitter-prism pairs. The emitters of the first row are labeled A1-A4, while the emitters of the second row are labeled B1-B4.

FIG. 4B shows the target illumination region 404 divided into a plurality of sub-regions 406, each of which is labeled by the emitter-prism pairs that illuminate that sub-region. As shown there, each sub-region 408 is illuminated by two different emitter-prism pairs, though it should be appreciated that each sub-region 408 may be illuminated by any number of different emitter-prism pairs as may be desired. For example, a first sub-region 408A is illuminated by corresponding substantially-overlapping output beams from emitter-prism pairs A1 and A3. In these instances, a prism surface of emitter-prism pair A1 has a similar orientation as a prism surface of emitter-prism pair A3, such that output beams created by these prism surfaces substantially overlap. It should be appreciated that sub-region 408A may include some overlap from other emitter-prism pairs (e.g., emitter prism pairs B1, B3, A2, and A4), but for the sake of illustration this overlap is not depicted in FIG. 4B.

A second sub-region 408B that is immediately adjacent to the first sub-region 408A may receive light from substantially-overlapping output beams generated by a different set of emitter-prism pairs B1 and B3. A third sub-region 408C that is immediately adjacent to the second sub-region 408B (such that the second sub-region 408B is positioned between the first sub-region 408 and the third sub-region 408C), may also be illuminated by substantially-overlapping output beams from the emitter-prism pairs A1 and A3. As a result, there may be one or more output beams (e.g., the output beams from emitter-prism pairs B1 and B3) between two output beams produced by a given emitter-prism pair (e.g., emitter-prism pair A1) without substantially overlapping.

In the variation shown in FIG. 4B, each output beam from a given emitter-prism pair that substantially overlaps with the target illumination region 406 will also substantially overlap an output beam generated from a different emitter-prism pair. In this way, there are two emitter-prism pairs that are able to illuminate any given sub-region, and thus the light emitting module 400 may provide illumination in a cost-effective manner that provides redundancy in the case of failure of an individual emitter. In the variation shown in FIG. 4B, each of the output beams of emitter-prism pair A1 substantially overlaps a corresponding output beam of emitter-prism pair A3. In other embodiments, a given emitter-prism pair may generate output beams that substantially overlap with multiple different emitter-prism pairs. For example, in other embodiments, the emitter-prism pair A3 may generate one or more output beams that substantially overlap with one or more corresponding output beams from emitter-prism pair A1, and may further generate one or more output beams that substantially overlap corresponding output beams generated by another emitter-prism pair (e.g., emitter-prism pair A2, B1, or the like).

In some variations, some of the emitter-prism pairs (e.g., emitter-prism pair A1) may illuminate light outside of the target illumination region 406. In instances where a diffractive optical element is used to create multiple replicas of the illumination from the array of emitter-prism pairs 402, one or more output beams generated by one or more emitter-prism pairs in one replica may substantially overlap one or more one or more output beams generated by one or more emitter-prism pairs in a different replica. For example, a diffractive optical element may arrange the replicas such that an output beam generated by emitter-prism pair A1 in one replica substantially overlaps an output beam generated by emitter-prism pair A4 in an adjacent replica. This may provide additional flexibility in providing illumination to a scene.

The particular arrangement shown in FIGS. 4A and 4B is just one manner in which the light emitting modules described herein may illuminate a target region, and it should be appreciated that the light emitting modules may utilize different combinations and arrangements of beam-splitting prisms (and, in some instances, microlenses) to provide a desired illumination to a target illumination region.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. A light emitting module, comprising:
a substrate having first and second surfaces;
an array of emitters, wherein a light-emitting surface of each of the array emitters is positioned to emit an input beam into the substrate through the second surface of the substrate; and
an array of beam-splitting prisms, which are formed on the first surface of the substrate, wherein each beam-splitting prism of the array of beam-splitting prisms:
is positioned to split the input beam emitted by a corresponding emitter of the array of emitters to generate a plurality of output beams; and
comprises a plurality of prism surfaces positioned to generate the plurality of output beams by redirecting respective portions of the input beam.

2. The light emitting module of claim 1, wherein the array of beam-splitting prisms comprises a first beam-splitting prism, wherein the plurality of prism surfaces of the first beam-splitting prism are arranged as a pyramid.

3. The light emitting module of claim 2, wherein an apex of the pyramid faces toward the second surface of the substrate.

4. The light emitting module of claim 1, wherein the array of beam-splitting prisms comprises a first beam-splitting prism, wherein:
the plurality of prism surfaces of the first beam-splitting prism comprises a first prism surface and a second prism surface.

5. The light emitting module of claim 4, wherein the first prism surface and the second prism surface are angled toward a common side of the light emitting module.

6. The light emitting module of claim 4, wherein the first prism surface and the second prism surface are angled toward different sides of the light emitting module.

7. The light emitting module of claim 1, wherein the array of emitters is formed on the second surface of the substrate.

8. The light emitting module of claim 7, wherein the array of emitters comprises vertical-cavity surface-emitting lasers (VCSELs).

9. The light emitting module of claim 1, wherein the array of beam-splitting prisms comprises a first beam-splitting prism and a second beam-splitting prism, wherein an output beam generated by the first beam-splitting prism substantially overlaps an output beam generated by the second beam-splitting prism in a scene illuminated by light emitting module.

10. The light emitting module of claim 1, further comprising a diffractive optical element positioned to create multiple replicas of the output beams generated by the array of beam-splitting prisms.

11. An optical device comprising:
a substrate having a first surface and a second surface, wherein the first surface is etched to define an array of beam-splitting prisms configured to split input beams of light that have been transmitted through the substrate, wherein:
each beam-splitting prism of the array of beam-splitting prisms comprises a plurality of prism surfaces arranged as a pyramid.

12. The optical device of claim 11, wherein the substrate comprises a III-V semiconductor substrate.

13. The optical device of claim 11, wherein the array of beam-splitting prisms comprises a first prism, wherein the plurality of prism surfaces of the first prism are arranged as a pyramid with an apex facing toward the second surface of the substrate.

14. The optical device of claim 11, wherein the array of beam-splitting prisms comprises a first prism, wherein the plurality of prism surfaces of the first prism are arranged as a pyramid with an apex facing away from the second surface of the substrate.

15. A light emitting module, comprising:
a substrate having first and second surfaces;
an array of emitters positioned to emit respective input beams into the substrate through the second surface of the substrate; and
an array of beam-splitting prisms configured to split each of the input beams to generate a corresponding plurality of output beams, wherein:
the first array of emitters is controllable to emit flood illumination to a target illumination region such that each location within the target illumination region is illuminated by output beams generated by at least two beam-splitting prisms of the array of beam-splitting prisms.

16. The light emitting module of claim 15, wherein:
the array of beam-splitting prisms comprises a first beam-splitting prism and a second beam-splitting prism; and
a first output beam generated by the first beam-splitting prism substantially overlaps with a first output beam generated by the second beam-splitting prism.

17. The light emitting module of claim 16, wherein a second output beam generated by the first beam-splitting prism substantially overlaps with a second output beam generated by the second beam-splitting prism.

18. The light emitting module of claim 15, wherein:
the array of beam-splitting prisms comprises a first beam-splitting prism and a second beam-splitting prism; and
a first output beam generated by the first beam-splitting prism is projected between first and second output beams generated by the second beam-splitting prism without substantially overlapping the first and second output beams generated by the second beam-splitting prism.

19. The light emitting module of claim 15, wherein:
the array of beam-splitting prisms comprises a first beam-splitting prism, a second beam-splitting prism, and a third beam-splitting prism;
a first output beam generated by the first beam-splitting prism substantially overlaps a first output beam generated by the second beam-splitting prism; and
a second output beam generated by the first beam-splitting prism substantially overlaps a first output beam generated by the third beam-splitting prism.

20. The light emitting module of claim 19, wherein a third output beam generated by the first beam-splitting prism substantially overlaps a second output beam generated by the second beam-splitting prism.
